(19) United States
(12) Patent Application Publication
(10) Pub. No.: US 2013/0214408 A1
(43) Pub. Date: Aug. 22, 2013

(54) Interposer Having Conductive Posts

(71) Applicants: Sam Ziqun Zhao, Irvine, CA (US); Rezaur Rahman Khan, Rancho Santa Margarita, CA (US)

(72) Inventors: Sam Ziqun Zhao, Irvine, CA (US); Rezaur Rahman Khan, Rancho Santa Margarita, CA (US)

(73) Assignee: BROADCOM CORPORATION, Irvine, CA (US)

(21) Appl. No.: 13/401,077

(22) Filed: Feb. 21, 2012

(51) Int. Cl. H01L 23/498; H05K 1/09; B23K 31/02; H05K 1/11

(52) U.S. Cl. 257/737; 174/261; 174/266; 174/257; 228/180.5; 257/E23.068

(57) ABSTRACT

There are disclosed herein various implementations of an interposer for use in semiconductor packaging. One exemplary implementation comprises a conductive post formed from a wire bond. A first end of the conductive post is mechanically joined to a conductive pad on a first surface of the interposer, while a second end of the conductive post is capable of making electrical connection to a contact body on an active surface of a semiconductor die. Such an interposer may include a rigid or flexible interposer dielectric. In one exemplary implementation, the interposer dielectric has a via formed therein, the conductive post being situated in the via and extending through a second surface of the interposer opposite the first surface.

### BACKGROUND

Packaging solutions continue to evolve to meet the ever more stringent design constraints imposed by electronic devices and systems with increased integrated circuit (IC) densities. One solution for enabling electrical connectivity between a packaging substrate or interposer and a semiconductor die utilizes a conductive post or pillar, such as a copper post, to provide an elevated contact point at a substrate or interposer surface.

According to one conventional approach for producing a copper post at an interposer surface, for example, a relatively thick copper layer formed on the surface is patterned and partially etched away so as to leave the copper posts as remainder. In another conventional method, conductive pads are formed through patterning of a thinner copper layer, such as a routing layer, and copper posts are plated onto the conductive pads. Both conventional techniques typically include several chemical processing steps in which reagents capable of causing significant environmental harm are utilized. In addition, although it may sometimes be advantageous to produce copper posts and routing traces on different surfaces of an interposer, both conventional techniques typically result in production of copper posts and routing traces on the same interposer surface.

### SUMMARY

The present disclosure is directed to an interposer having conductive posts, substantially as shown in and/or described in connection with at least one of the figures, and as set forth more completely in the claims.

### BRIEF DESCRIPTION OF THE DRAWINGS

FIG. 1A shows a cross-sectional view of one implementation of an interposer having conductive posts electrically connected to a semiconductor die.

FIG. 1B shows a cross-sectional expanded view of a portion of the interposer having conductive posts shown in FIG. 1A.

FIG. 2 shows a flowchart presenting an exemplary method for producing a conductive post on an interposer.

FIG. 3A shows a cross-sectional view of another implementation of an interposer having conductive posts electrically connected to a semiconductor die.

FIG. 3B shows a cross-sectional expanded view of a portion of the interposer having conductive posts shown in FIG. 3A.

FIG. 4 shows a flowchart presenting another exemplary method for producing a conductive post on an interposer.

### DETAILED DESCRIPTION

The following description contains specific information pertaining to implementations in the present disclosure. One skilled in the art will recognize that the present disclosure may be implemented in a manner different from that specifically discussed herein. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

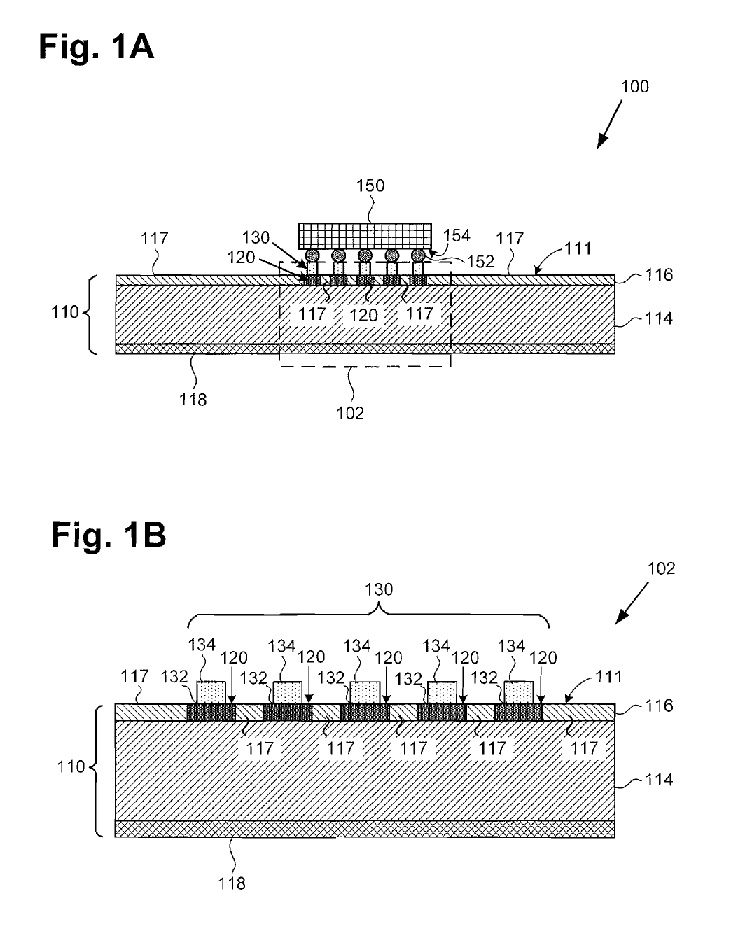

FIG. 1A shows a cross-sectional view of one implementation of an interposer having conductive posts. As shown in FIG. 1A, semiconductor package 100 includes interposer 110 having conductive posts 130 electrically coupling interposer 110 to contact bodies 152 on active surface 154 of semiconductor die 150. As further shown in FIG. 1A, interposer 110 includes interposer dielectric 114, patterned routing layer 116 formed at first surface 111 of interposer 110, and protective layer 118 formed at a second interposer surface opposite first surface 111. According to the specific example shown in FIG. 1A, patterned routing layer 116 includes conductive pads 120 produced, for example, through patterning of a routing metal at first surface 111 of interposer 110, as well as passivation portions 117 formed between and bordering conductive pads 120. Also shown in FIG. 1A is region 102 corresponding to a portion of interposer 110 including conductive pads 120 and conductive posts 130. It is noted that region 102 is shown in an expanded view in FIG. 1B and will be described in greater detail below.

Interposer dielectric 114 may be formed of a rigid substrate material, such as fiber reinforced bismaleimide triazine (BT), FR-4, silicon, glass, or ceramic, for example. Alternatively, interposer dielectric 114 may be a flexible dielectric formed of a polyimide film or other suitable tape material. As noted above, patterned routing layer 116 at first surface 111 of interposer 110 includes passivation portions 117 and conductive pads 120. Conductive pads 120 may be formed of copper (Cu), for example through patterning of a routing layer formed from copper, or may be formed from any other metal suitable for use as a conductive trace or pad on first surface 111. Passivation portions 117 may be formed of solder resist, for example, or any other substantially inert material suitable to provide a passivation barrier at first surface 111.

According to the specific example shown in FIG. 1, protective layer 118 is formed at a second surface of interposer 110. Protective layer 118 may be formed of any suitable passivation material. In one implementation, for example, protective layer 118 and passivation portions 117 may be formed of the same material, such as a solder resist. It is noted that in some implementations in which interposer dielectric 114 is formed of a robust and reliable dielectric material, protective layer 118 may be omitted.

As shown in FIG. 1A, interposer 110 includes conductive posts 130 providing electrical connection to active surface 154 of semiconductor die 150. Semiconductor die 150 may be a packaged or unpackaged die, for example. Although semiconductor die 150 is shown in a flip chip configuration, in FIG. 1A, that representation is merely exemplary, and in other implementations, semiconductor die 150 may exhibit a different configuration. Conductive posts 130 are electrically connected to active surface 154 of semiconductor die 150 through contact bodies 152 on active surface 154. Depending upon the specific implementation of semiconductor package 100, as well as the dimensions and pitch of semiconductor die 150, contact bodies 152 may be solder bumps or balls, or may be formed as micro-bumps, for example.

It is noted that although semiconductor package 100 is described as including interposer 110, in other implementations, interposer 110 may correspond to a packaging substrate other than an interposer, such as a primary packaging substrate, for example. Moreover, it is to be understood that semiconductor package 100 may include other features typically found in a semiconductor package, but not shown in FIG. 1A in the interest of conceptual clarity. For example, in some implementations, interposer 110 may reside over another interposer, or over a primary packaging substrate, such as a thin core or coreless substrate, and may include additional routing traces not explicitly shown in FIG. 1A.

Referring to FIG. 1B, FIG. 1B shows an expanded view of region 102. As shown in FIG. 1B, region 102 includes a portion of interposer 110 including a portion of patterned routing layer 116 having conductive pads 120, and conductive posts 130 joined to conductive pads 120. Also shown in FIG. 1B are passivation portions 117 of patterned routing layer 116, as well as portions of interposer dielectric 114 and protective layer 118 corresponding to region 102, in FIG. 1A.

According to the present concepts, conductive posts 130 are formed of wire bond, such as copper or gold (Au) wire bond, for example, or any other suitable conductive wire bond material. As a specific example, conductive posts 130 may be copper posts formed from copper wire bond and may have a diameter in a range from approximately 0.5 mm to approximately 1.5 mm. As shown in FIG. 1B, each of conductive posts 130 has first end 132 joined to a respective conductive pad 120 on first surface 111 of interposer 110, and second end 134 capable of electrical connection to a contact body on an active surface of a semiconductor die, as further shown by the connection to contact bodies 152 on active surface 154 of semiconductor die 150 depicted in FIG. 1A, for example. Moreover, conductive posts 130 may be formed by mechanically joining first ends 132 of conductive posts 130 to their respective conductive pads 120, for example, by heating first ends 132 of conductive posts 130 and applying pressure suitable to join first ends 132 of conductive posts 130 to conductive pads 120.

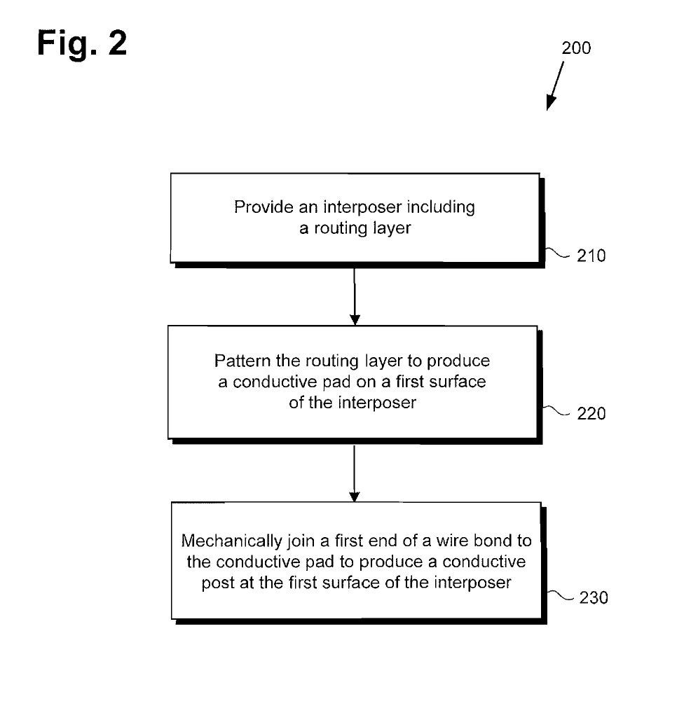

Some of the features and advantages of the implementation shown in FIGS. 1A and 1B will now be further described by reference to FIG. 2, which shows flowchart 200 presenting an exemplary method for producing a conductive post on an interposer. It is noted that the method described by flowchart 200 may be performed on a portion of an interposer or packaging substrate, which includes, among other features, a routing layer suitable for formation of conductive traces and/or conductive pads, for example.

Flowchart 200 begins by providing an interposer including a routing layer (210). Referring to FIGS. 1A and 1B, for example, flowchart 200 may begin by providing interposer 110 including interposer dielectric 114 and protective layer 118, prior to patterning of a routing layer at first surface 111. Maintaining reference to FIGS. 1A and 1B, flowchart 200 continues by patterning the routing layer to produce conductive pads 120 on first surface 111 of interposer 110 (220). As noted above, conductive pads 120 may be formed of copper, for example, through patterning of a routing layer formed from copper, or they may be formed of any other metal suitable for use as a conductive trace or pad on first surface 111. Patterning of the routing layer to produce conductive pads 120 may be performed using any suitable technique, such as masking and etching of the routing layer, for example.

Referring to FIG. 1B, flowchart 200 continues by mechanically joining first end(s) 132 of wire bond to conductive pad(s) 120 to produce conductive post(s) 130 at first surface 111 of interposer 110 (230). A mechanical joint connecting any of first ends 132 of conductive posts 130 to its respective conductive pad 120 can be formed by heating first end 132 and placing first end 132 into contact with conductive pad 120, for example. In addition, in some implementations, it may be advantageous to utilize a combination of heat and pressure to mechanically join first end 132 to conductive pad 120 to produce conductive post 130.

In contrast to the process described by reference to flowchart 200 and FIGS. 1A and 1B, conventional approaches to forming conductive posts typically employ relatively time consuming and chemically intensive etching or plating processes. Those conventional approaches entail several disadvantages that are substantially reduced or entirely overcome through implementation of the concepts disclosed herein.

For example, although conventional techniques are typically limited with respect to the height of a conductive post produced thereby, use of wire bond for formation of a conductive post, as disclosed herein, enables production of a conductive post having substantially any desired height above a surface, such as first surface 111, in FIGS. 1A and 1B. That is to say, because wire bond may be trimmed so as to have substantially any desired length, a conductive post formed from such wire bond may assume substantially any desired height, such as a height of approximately 60 μm to approximately 90 μm, for example, or a greater or even significantly greater height if so desired. In addition, mechanically joining first ends 132 to conductive pads 120 so as to produce conductive posts 130 avoids the relatively costly and chemical reagent intensive processing inherent to electrochemical or electrolytic plating of conductive posts, or inherent to etching of a sufficiently thick metal layer to produce conductive posts, as typically required by conventional methods.

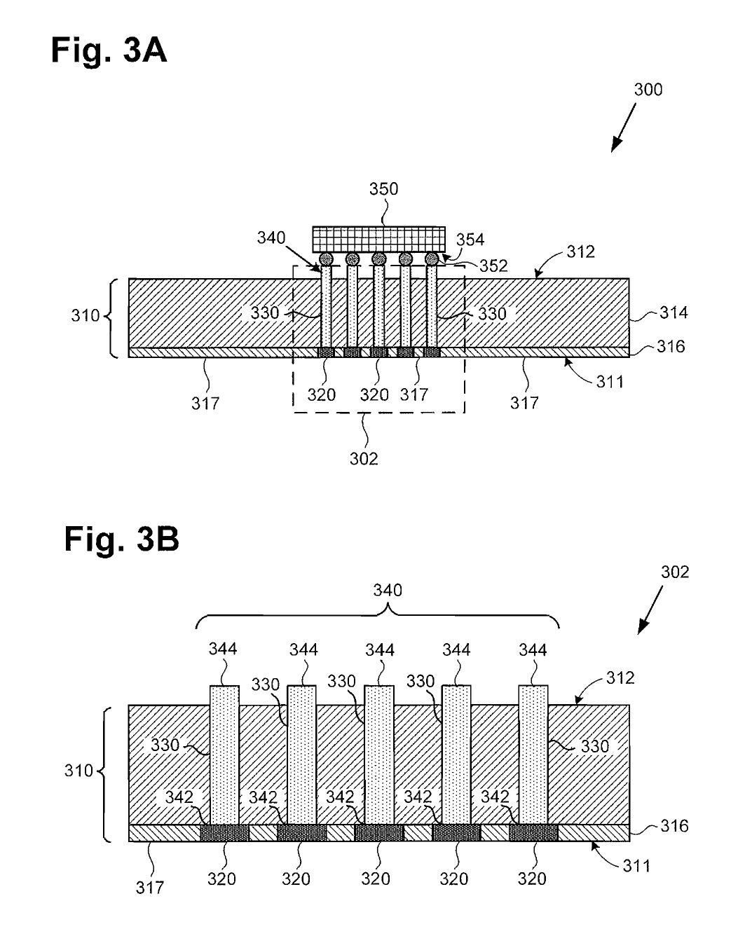

Moving now to FIG. 3A, FIG. 3A shows a cross-sectional view of another implementation of an interposer having conductive posts. As shown in FIG. 3A, semiconductor package 300 includes interposer 310 having conductive posts 340 electrically coupling interposer 310 to contact bodies 352 on active surface 354 of semiconductor die 350. As further shown in FIG. 3A, interposer 310 includes interposer dielectric 314, and patterned routing layer 316 at first surface 311 of interposer 310. According to the example implementation shown in FIG. 3A, patterned routing layer 316 includes conductive pads 320 and passivation portions 317 formed between and bordering conductive pads 320.

Interposer 310 including interposer dielectric 314 and patterned routing layer 316, first surface 311 of interposer 310, and semiconductor die 350 having contact bodies 352 on active surface 354, correspond in general to interposer 110 including interposer dielectric 114 and patterned routing layer 116, first surface 111 of interposer 110, and semiconductor die 150 having contact bodies 152 on active surface 154, shown in FIG. 1A. However, and unlike FIG. 1A, according to the implementation shown in FIG. 3A, semiconductor die 350 is electrically connected to interposer 310 at second surface 312 of interposer 310, opposite first surface 311. In addition, and again unlike the structures shown in FIG. 1A, interposer 310 includes vias 330 formed on second surface 312 of interposer 310 and extending through interposer dielectric 314 to expose conductive pads 320.

Moreover, according the present implementation, interposer 310 includes conductive posts 340, each of which is shown to be situated in a respective via 330 so as to be mechanically joined to a respective conductive pad 320 on first surface 311 while extending through second surface 312 of interposer 310 so as to be capable of electrical connection to contact bodies 352 on active surface 354 of semiconductor die 350 at second surface 312. Also shown in FIG. 3A is region 302 corresponding to a portion of interposer 310 including conductive pads 320, vias 330, and conductive posts 340. It is noted that, as was the corresponding case in FIGS. 1A and 1B, region 302 in FIG. 3A is shown in an expanded view in FIG. 3B.

Like interposer dielectric 114, in FIGS. 1A and 1B, interposer dielectric 314 may be formed of a rigid substrate material such as BT, FR-4, silicon, glass, or ceramic. Alternatively, interposer dielectric 314 may be a flexible dielectric formed of a polyimide film or other suitable tape material. According to the implementation of FIG. 3A, interposer 310 includes only one routing layer, which has been patterned and is shown in semiconductor package 300 as patterned routing layer 316 at first surface 311. Patterned routing layer 316 includes passivation portions 317 and conductive pads 320. Conductive pads 320 may be formed of copper or any other metal suitable for use as a conductive trace or pad on first surface 311 of interposer 310. Passivation portions 317 may be formed of solder resist or any other substantially inert material suitable to provide a passivation barrier at first surface 311. It is noted that although the implementation of FIG. 3A omits a protective layer at second surface 312 of interposer 310, that omission is merely exemplary. In some implementations, interposer 310 may include a protective layer at second surface 312, such as a protective layer corresponding to protective layer 118, in FIG. 1A.

As was true of semiconductor package 100, in FIG. 1A, although semiconductor package 300 is described as including interposer 310, in other implementations, interposer 310 may correspond to a packaging substrate other than an interposer, such as a primary packaging substrate, for example. Moreover, it is to be understood that semiconductor package 300 may include other features typically found in a semiconductor package, but not shown in FIG. 3A in the interest of conceptual clarity. For example, in some implementations, interposer 310 may reside over another interposer, or over a primary packaging substrate, such as a thin core or coreless substrate, and may include additional routing traces not explicitly shown in FIG. 3A.

Referring to FIG. 3B, FIG. 3B shows an expanded view of region 302. As shown in FIG. 3B, region 302 includes a portion of interposer 310 including a portion of patterned routing layer 316 having conductive pads 320 on first surface 311, vias 330 formed on second surface 312 and extending through interposer dielectric 314, and conductive posts 340 situated in vias 330, extending through second surface 312, and joined to conductive pads 320 on first surface 311. Also shown in FIG. 3B are passivation portions 317 of patterned routing layer 316 at first surface 311.

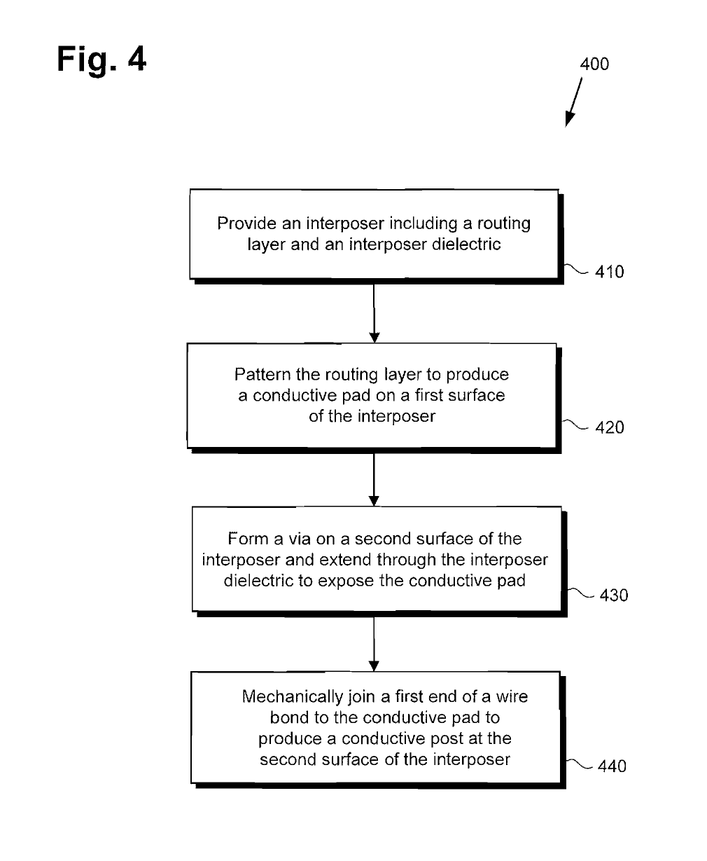

Some of the features and advantages of the implementation shown in FIGS. 3A and 3B will now be further described by reference to FIG. 4, which shows flowchart 400 presenting another exemplary method for producing a conductive post on an interposer. It is noted that the method described by flowchart 400 may be performed on a portion of an interposer or packaging substrate, which includes, among other features, an interposer or substrate dielectric suitable for formation of vias and a routing layer suitable for formation of conductive traces and/or conductive pads, for example.

Flowchart 400 begins by providing an interposer including a routing layer and an interposer dielectric (410). Referring to FIGS. 3A and 3B, for example, flowchart 400 may begin by providing interposer 310 including interposer dielectric 314 and a routing layer at first surface 311 (routing layer represented in FIGS. 3A and 3B after subsequent patterning to form patterned routing layer 316). Flowchart 400 continues by patterning the routing layer to produce conductive pads 320 on first surface 311 of interposer 310 as part of patterned routing layer 316 (420). As noted above, conductive pads 420 may be formed of copper, for example, through patterning of a routing layer formed from copper, or they may be formed of any other metal suitable for use as a conductive trace or pad on first surface 311. Patterning of the routing layer to produce conductive pads 320 may be performed using any suitable technique, such as masking and etching of the routing layer, for example.

Continuing with reference to FIGS. 3A and 313, flowchart 400 continues by forming vias 330 on second surface 312 of interposer 310 and extending through interposer dielectric 314 to expose conductive pads 320 (430). Depending upon the implementation of interposer 310 and/or the material from which interposer dielectric 314 is formed, for example, vias 330 may be formed by an etching process, by drilling vias 330, or through a direct laser ablation process, e.g., use of a “laser drill.” In instances in which interposer dielectric 314 corresponds to an interposer or package substrate, vias 330 may be understood to he through-substrate vias, which, in addition to being etched or drilled, may be lined with an additional dielectric layer, depending upon the dielectric properties of interposer dielectric 314.

Referring to FIG. 3B, flowchart 400 continues by mechanically joining first end(s) 342 of wire bond to conductive pad(s) 320 to produce conductive post(s) 340 at second surface 312 of interposer 310 (440). A mechanical joint connecting any first end 342 of conductive posts 340 to its respective conductive pad 320 can be formed by inserting first end 342 into its respective via 330, heating first end 342, and placing first end 342 in contact with its respective conductive pad 320, for example. In addition, in some implementations, it may be advantageous to utilize a combination of heat and pressure to mechanically join first end 342 to conductive pad 320 so as to produce conductive post 340. Conductive posts 340 may be formed from copper or gold wire bond, for example, or any other suitable conductive wire bond material, such as a metal alloy. To reiterate the example dimensions described above by reference to FIG. 1B, conductive posts 340 may be copper posts formed from copper wire bond and may have a diameter in a range from approximately 0.5 mm to approximately 1.5 mm.

As shown in FIG. 3B, each of conductive posts 340 has first end 342 joined to a respective conductive pad 320 on first surface 311 of interposer 310, and second end 344 capable of electrical connection to a contact body on an active surface of a semiconductor die located at a second surface 312 of interposer 310, opposite first surface 311, as further shown by the connection to contact bodies 352 on active surface 354 of semiconductor die 350 depicted in FIG. 3A, for example. As a result, the present implementation enables use of an interposer having only one routing layer formed on one surface of the interposer to produce conductive posts capable of electrical connection at an opposite surface of the interposer.

Thus, by using a wire bond to form a conductive post and by mechanically joining a first end of the wire bond to a conductive pad patterned on an interposer or package substrate, various implementations of the concepts disclosed herein advantageously enable significantly more efficient production of conductive posts for use in semiconductor packaging, relative to the conventional art, while concurrently reducing the use of environmentally harmful chemical reagents. In addition, the disclosed implementations advantageously enable production of conductive posts having substantially any desired height. Moreover, the present application discloses implementations wherein a conductive post having a first end mechanically joined to a conductive pad on a first surface of an interposer or package substrate, has a second end capable of forming an electrical connection to a contact body on an active surface of a semiconductor device situated at a second surface of the interposer or package substrate, opposite the first surface. As a result, the present concepts advantageously enable use of an interposer have only one routing layer to form an electrical connection on an interposer surface opposite the surface on which the routing layer is formed.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the spirit and the scope of those concepts. As such, the described implementations are to be considered in all respects as illustrative and not restrictive. It should also be understood that the present application is not limited to the particular implementations described herein, but many rearrangements, modifications, and substitutions are possible without departing from the scope of the present disclosure.

1. An interposer for use in semiconductor packaging, said interposer comprising:
a conductive post formed from a wire bond;
a first end of said conductive post mechanically joined to a conductive pad on a first surface of said interposer;
a second end of said conductive post being capable of electrical connection to a contact body on an active surface of a semiconductor die.

2. The interposer of claim 1, wherein said interposer further comprises a rigid interposer dielectric.

3. The interposer of claim 1, wherein said interposer further comprises a flexible interposer dielectric.

4. The interposer of claim 1, further comprising an interposer dielectric having a via formed therein, said conductive post situated in said via and extending through a second surface of said interposer opposite said first surface.

5. The interposer of claim 1, wherein said conductive post comprises copper (Cu).

6. The interposer of claim 1, wherein said conductive post comprises gold (Au).

7. The interposer of claim 1, wherein said interposer includes a routing layer, said routing layer being patterned to produce said conductive pad.

8. A semiconductor package comprising:
an interposer and a semiconductor die;
a conductive post formed from a wire bond, wherein a first end of said conductive post is mechanically joined to a conductive pad on a first surface of said interposer;
a second end of said conductive post being electrically connected to a contact body on an active surface of said semiconductor die.

9. The semiconductor package of claim 8, wherein said active surface of said semiconductor die is situated over said first surface of said interposer.

10. The semiconductor package of claim 8, wherein said interposer is formed using one of a rigid interposer dielectric and a flexible interposer dielectric.

11. The semiconductor package of claim 8, wherein said interposer comprises an interposer dielectric having a via formed therein, said conductive post situated in said via and extending through a second surface of said interposer opposite said first surface.

12. The semiconductor package of claim 8, wherein said active surface of said semiconductor die is situated over a second surface of said interposer opposite said first surface of said interposer.

13. The semiconductor package of claim 8, wherein said conductive post comprises copper (Cu).

14. The semiconductor package of claim 8, wherein said conductive post comprises gold (Au).

15-20. (canceled)
